(19) United States
(12) Patent Application Publication
(10) Pub. No.: US 2026/0033211 A1
(43) Pub. Date: Jan. 29, 2026

(54) OLED DISPLAY PANEL AND MANUFACTURING METHOD THEREOF

(71) Applicant: HKC CORPORATION LIMITED, SHENZHEN (CN)

(72) Inventors: Yangling TANG, SHENZHEN (CN); Zhisheng XIE, SHENZHEN (CN); Qin LIANG, SHENZHEN (CN); Xiufeng ZHOU, SHENZHEN (CN); Pei XU, SHENZHEN (CN)

(73) Assignee: HKC CORPORATION LIMITED, SHENZHEN (CN)

(21) Appl. No.: 19/271,852

(22) Filed: Jul. 17, 2025

(30) Foreign Application Priority Data
Jul. 29, 2024 (CN) 202411027211.4

(51) Int. Cl. H10K 59/80; H10K 59/12; H10K 59/122

(52) U.S. Cl. CPC H10K 59/80515; H10K 59/1201; H10K 59/122; H10K 59/80517

(57) ABSTRACT

An OLED display panel and a manufacturing method thereof are provided. The method may include: fabricating a first anode electrode, a second anode electrode, and a third anode electrode; fabricating a first OLED layer on surfaces of the first anode electrode, the second anode electrode, and the third anode electrode; etching away the first OLED layer on the second anode electrode and the third anode electrode; fabricating a second OLED layer on the first OLED layer, the second anode electrode, and the third anode electrode; etching away the second OLED layer on the first OLED layer and the third anode electrode; fabricating a third OLED layer on the first OLED layer, the second OLED, and the third anode electrode; etching away the third OLED layer on the surfaces of the first OLED layer and the second OLED layer, to form the OLED display panel.

### CROSS REFERENCE TO RELATED APPLICATIONS

This application claims priority to Chinese Patent Application No. 202411027211.4, entitled “OLED display panel and manufacturing method thereof”, filed on Jul. 29, 2024, which is herein incorporated by reference in its entirety.

### TECHNICAL FIELD

The present disclosure relates to the field of display technologies, in particularly to a display panel and a manufacturing method thereof.

### BACKGROUND

Compared with liquid-crystal display (LCD) panels, organic light emitting diode (OLED) display panels may have many advantages such as fully solid-state, active light emission, high brightness, high contrast, ultra-thin, low power consumption, no viewing angle limitation, and wide operating temperature range or the like, and thus have received more and more attention.

Under a new process route scheme for overhanging structure without using mask, the overhanging structure may need to be arranged on the pixel define layer (PDL), so as to facilitate evaporation of film layers between various segments of pixels and formation of independent packaging. In a conventional manufacturing procedure process route of the overhanging structure OLED, anodes of a part of the sub-pixels may undergo one etching process or two etching processes. During the etching process, whether acidic or alkaline liquid is used, the properties of anode surfaces may all be damaged and modified, resulting in deteriorated performance of an OLED device.

### SUMMARY

According to a first aspect of the present disclosure, a manufacturing method of an OLED display panel is provided. The manufacturing method may include: providing a substrate; fabricating a first anode electrode, a second anode electrode, and a third anode electrode on the substrate, wherein a corrosion resistance of the second anode electrode is better than that of the first anode electrode, and a corrosion resistance of the third anode electrode is better than that of the first anode electrode; fabricating a first OLED layer on a surface of the first anode electrode, a surface of the second anode electrode, and a surface of the third anode electrode; etching away the first OLED layer on the surface of the second anode electrode and the first OLED layer on the surface of the third anode electrode to form a first sub-pixel; fabricating a second OLED layer on a surfaces of the first OLED layer, the surface of the second anode electrode, and the surface of the third anode electrode; etching away the second OLED layer on the surface of the first OLED layer and the second OLED layer on the surface of the third anode electrode, to form the first sub-pixel and the second sub-pixel; fabricating a third OLED layer on the surface of the first OLED layer, a surface of the second OLED, and the surface of the third anode electrode; etching away the third OLED layer on the surface of the first OLED layer and the third OLED layer on the surface of the second OLED layer, to form the OLED display panel comprising the first sub-pixel, the second sub-pixel, and a third sub-pixel.

According to a second aspect of the present disclosure, an OLED display panel may be provided. The OLED display panel may include: a substrate; a first anode electrode, a second anode electrode and a third anode electrode; a pixel definition layer; and, a first OLED layer, a second OLED layer and a third OLED layer. The first anode electrode, the second anode electrode and the third anode electrode may be spaced apart from each other and arranged on a surface of the substrate. A corrosion resistance of the second anode electrode may be better than that of the first anode electrode. A corrosion resistance of the third anode electrode may be better than that of the first anode electrode. The pixel definition layer may be arranged at interval positions among the first anode electrode, the second anode electrode, and the third anode electrode, and may partially extend to a surface of the first anode electrode, a surface of the second anode electrode, and a surface of the third anode electrode. The first OLED layer may be arranged on the surface of the first anode electrode. The second OLED layer may be arranged on the surface of the second anode electrode. The third OLED layer may be arranged on the surface of the third anode electrode.

### BRIEF DESCRIPTION OF THE DRAWINGS

In order to more clearly illustrate technical solutions in the present application, the drawings required in the description of the embodiments will be briefly introduced below. Obviously, the drawings in the following description are only some embodiments of the present application. For those of ordinary skills in the art, other drawings could be obtained based on these drawings without creative efforts.

FIG. 1 is a schematic flowchart of an embodiment of a manufacturing method of an OLED display panel according to the present disclosure.

FIG. 2a is a schematic structural diagram of a first specific embodiment matching with the operation at block S12 of FIG. 1.

FIG. 2b is a schematic structural diagram of a second specific embodiment matching with the operation at block S12 of FIG. 1.

FIG. 3 is a schematic structural diagram of a specific embodiment matching with the operation at block S13 of FIG. 1.

FIG. 4 is a schematic structural diagram of a specific embodiment matching with the operation at block S14 of FIG. 1.

FIG. 5 is a schematic structural diagram of a specific embodiment matching with the operation at block S15 of FIG. 1.

FIG. 6 is a schematic structural diagram of a specific embodiment matching with the operation at block S16 of FIG. 1.

FIG. 7 is a schematic structural diagram of a specific embodiment matching with the operation at block S17 of FIG. 1.

FIG. 8 is a schematic structural diagram of a specific embodiment matching with the operation at block S18 of FIG. 1.

FIG. 9 is a schematic structural diagram of a specific embodiment of an OLED display panel according to the present disclosure.

### DETAILED DESCRIPTION

The following will be a clear and through description of the technical solutions in the embodiments of the present disclosure in conjunction with the accompanying drawings in the embodiments of the present disclosure. It is clear that, the described embodiments are only a part of the embodiments of the present disclosure, not all of them. Based on the embodiments of the present disclosure, all other embodiments obtained by a person of ordinary skill in the art without creative efforts would fall within the protection scope of the present disclosure.

The terms adopted in the present disclosure are intended solely for describing particular embodiments and are not intended to limit. The singular forms of “a”, “the” and “this” adopted in embodiments of the present disclosure and the claim set are also intended to include the plural forms, unless clearly indicated otherwise in the above context. “A plurality of” may generally include at least two, but may not exclude the situation of including at least one.

The term “and/or” is merely an associating relationship for describing the associated objects and indicates that there could be three relationships between the associated objects. For example, A and/or B may represent three situations: only A exists, A and B exist simultaneously, and only B exists. In the present disclosure, the character “/” generally indicates an “or” relationship between the associated objects before and after the character “/”. The terms “first”, “second” or the like in the description, claims and the figures described above are used for distinguishing between similar items, and are not necessarily for describing a particular sequential or chronological order.

The terms “including”, “comprising”, or any other variation thereof adopted in the present disclosure are intended to cover non-exclusive inclusion, such that a process, a method, an article or a device comprising a serial of elements includes not only those elements, but also other elements not expressly listed, or elements inherent to such a process, a method, an article or a device. When there is no further limitation, an element defined by the statement “including . . . ” does not preclude the existence of another identical element in the process, method, article or apparatus that includes that element.

If the embodiments of the present disclosure involve directional indications (such as up, down, left, right, front, back . . . ), these directional indications may only be used to explain relative positional relationship and movement or the like of various components in a specific posture (as illustrated in the attached drawings). If this specific posture changes, these directional indications may also change accordingly.

Reference to “embodiment” herein means that a specific feature, structure, or characteristic described in conjunction with the embodiments may be included in at least one embodiment of the present disclosure. The appearance of this phrase in each location of the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

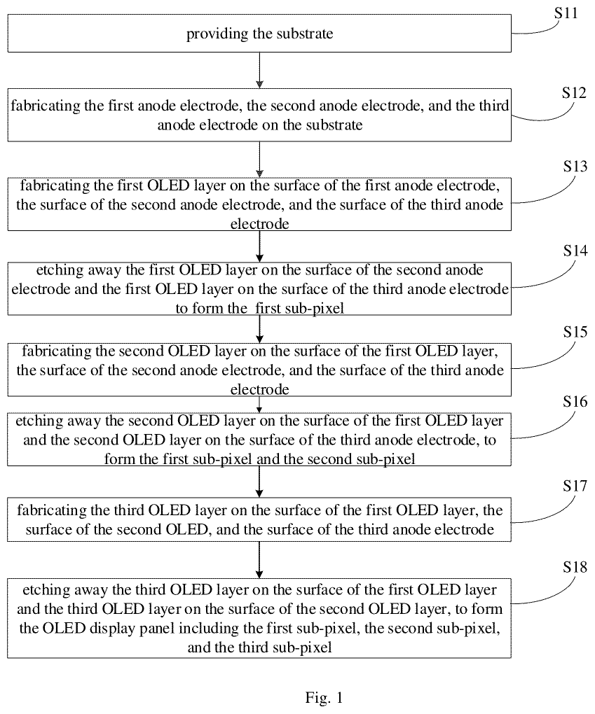

The present disclosure provides a manufacturing method of an OLED display panel. Specifically, as illustrated in FIG. 1, FIG. 1 is a schematic flowchart of an embodiment of a manufacturing method of an OLED display panel according to the present disclosure. As illustrated in FIG. 1, the manufacturing method may include operations at blocks illustrated in FIG. 1.

The operation at block S11: providing a substrate.

The substrate may include a base layer, a driving layer, and a planarization layer arranged on a side of the driving layer away from the base layer, which is not limited herein.

The operation of providing the substrate may include defining grooves on surface locations of the planarization layer of the substrate matching with the following-mentioned second anode electrode 112 and third anode electrode 113, so that the surfaces of the second anode electrode 112 and the third anode electrode 113 are on the same horizontal plane as the surface of the following-mentioned first anode electrode 111, thereby eliminating a height difference between the second anode electrode 112 and the first anode electrode 111, and eliminating a height difference between the third anode electrode 113 and the first anode electrode 111. The depth of the grooves may be set according to the thickness difference between the second anode electrode 112 and the first anode electrode 111 and according to the thickness difference between the third anode electrode 113 and the first anode electrode 111. Specifically, the depth of the groove for the second anode electrode 112 may further be different from that of the groove for the third anode electrode 113. The depth of the groove for the second anode electrode 112 may be specifically designed according to the thickness of the protective layer on the surface of the second anode electrode 112, the depth of the groove for the third anode electrode 113 may be specifically designed according to the thickness of the protective layer on the surface of the third anode electrode 113, which are not limited herein.

The operation at block S12: fabricating a first anode electrode, a second anode electrode, and a third anode electrode on the substrate.

The first anode electrode, the second anode electrode, and the third anode electrode may be arranged at intervals. The first anode electrode may be an anode electrode configured for forming a first sub-pixel. The second anode electrode may be an anode electrode configured for forming a second sub-pixel. The third anode electrode may be an anode electrode configured for forming a third sub-pixel. Each pixel unit may include the first sub-pixel, the second sub-pixel, and the third sub-pixel.

The first anode electrode may be made of a different material from that of the second anode electrode. The first anode electrode may be made of a different material from that of the third anode electrode. A corrosion resistance of the second anode electrode may be better than that of the first anode electrode. A corrosion resistance of the third anode electrode may be better than that of the first anode electrode. That is to say, the second anode electrode and the third anode electrode may be more corrosion-resistant. The second anode electrode and the third anode electrode may be made of a same material or different materials. Specifically, the second anode electrode and the third anode electrode may each include a corrosion-resistant material. The corrosion-resistant material may preferably be a conductive metal oxide. In the present embodiment, the corrosion-resistant material may preferably be molybdenum oxide or tungsten oxide.

In a first specific embodiment, a surface of the first anode electrode may be ITO, and the surface of any of the second anode electrode and the third anode electrode may be the molybdenum oxide or the tungsten oxide. The operation at block S12 may specifically include the following operations: fabricating the first anode electrode, the second anode electrode, and the third anode electrode on the substrate respectively. In some embodiments, the first anode electrode may be an ITO electrode layer. The second anode electrode and the third anode electrode may be electrodes formed of the corrosion-resistant material. The corrosion-resistant material may include the molybdenum oxide (MoOx) or the tungsten oxide (WOx), or the like. The ITO may have a high transparency degree in the visible light region, a high electrical conductivity, and a high work function required for a low barrier for hole transport, and may be widely used as a display electrode of the display panel. The first anode electrode may specifically include AL/ITO, Ag/ITO, or the like. The second anode electrode and the third anode electrode may specifically include AL/WOx, Ag/WOx, Ag/MoOx, or the like.

In a second specific embodiment, the surface of the first anode electrode may be the ITO. The second anode electrode may include the ITO and a protective layer arranged on a surface of the ITO. The protective layer may include the molybdenum oxide or the tungsten oxide. The operation at block S12 may specifically include the following operations: fabricating a patterned ITO layer on the substrate and obtaining a plurality of first anode electrodes; fabricating protective layers on surfaces of two of the ITO layers (or the first anode electrodes) in each pixel unit, and obtaining the second anode electrode and the third anode electrode. Every three sub-pixels may form one pixel unit. In the present embodiment, the first anode electrode may include an ITO layer, each of the second anode electrode and the third anode electrode may include an ITO layer and a protective layer arranged on the surface of the ITO layer. The protective layer may be formed of the corrosion-resistant material such as the molybdenum oxide, the tungsten oxide, or the like. Specifically, the second anode electrode and the third anode electrode may specifically be ITO/Ag/WOx, ITO/Ag/MoOx, or the like. In the present embodiment, the operation may specifically include the following operations: forming an entire-surface ITO layer on the substrate; patterning and etching the ITO layer into a plurality of spaced first anode electrodes; and fabricating protective layers on the surfaces of two of the first anode electrodes in each pixel unit respectively, so as to form the second anode electrode and the third anode electrode. In the present embodiment, the protective layer of the second anode electrode may be different from or the same as that of the third anode electrode. In some embodiments, the thickness of the protective layer in the third anode electrode may be greater than that of the protective layer in the second anode electrode, this is because the third anode electrode needs to be etched twice, while the second anode electrode only needs to be etched once.

Since the protective layer is added, which may be equivalent to adding a film layer which may change a microcavity between the anode electrode and a cathode electrode, which is unfavorable to stability of the microcavity of the film layer. Therefore, in the present embodiment, the anode electrode of the first sub-pixel may not be protected by a protective layer, and only the second/third sub-pixels are protected by the protective layers.

Since the thickness of the protective layer may affect a microcavity length of the OLED device, the thickness of the protective layer may preferably range from 10 A to 200 A. Further, according to process capabilities, the thickness of the protective layer may preferably range from 75 A to 150 A.

Compared with the second specific embodiment, the first specific embodiment may solve a problem of thickening of the microcavity caused by adding the protective layer on the surface of the ITO anode electrode. However, in terms of a manufacturing procedure, the first specific embodiment may be more complex and more difficult than the second specific embodiment.

After the operation at block S12, the manufacturing method may further include: fabricating a pixel definition layer on the surface of the substrate, and exposing the surface of the first anode electrode, the surface of the second anode electrode, and the surface of the third anode electrode; and fabricating an overhanging structure on a surface of the pixel definition layer, so as to facilitate evaporation of the OLED layer. The overhanging structure may include a supporting portion and an eave portion. An area of the eave portion may be greater than that of the supporting portion.

The OLED layer may include an organic light-emitting layer, a cathode layer, an encapsulating layer, or the like. The organic light-emitting layer may include a blue organic light-emitting layer, a green organic light-emitting layer, a red organic light-emitting layer, or the like.

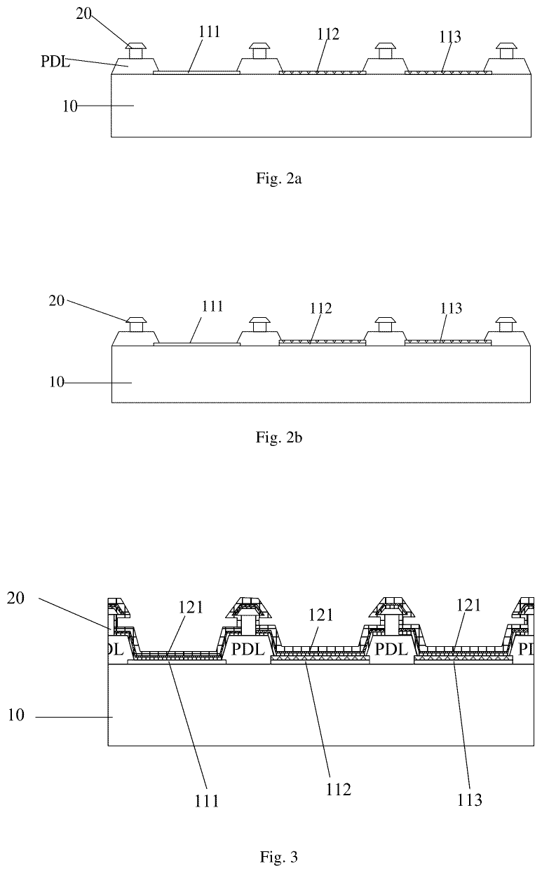

The present operation may be illustrated in FIG. 2a and FIG. 2b. FIG. 2a is a schematic structural diagram of a first specific embodiment matching with the operation at block S12 of FIG. 1, FIG. 2b is a schematic structural diagram of a second specific embodiment matching with the operation at block S12 of FIG. 1. As illustrated in FIG. 2a and FIG. 2b, the OLED display panel may include a substrate 10. A first anode electrode 111, a second anode electrode 112, and a third anode electrode 113 may be included within one pixel unit on the substrate 10. As illustrated in FIG. 2a, the first anode electrode 111 may be an ITO anode electrode. The second anode electrode 112 and the third anode electrode 113 may be anode electrodes made of the corrosion-resistant material.

As illustrated in FIG. 2b, the first anode electrode 111 may be the ITO anode electrode. The second anode electrode 112 and the third anode electrode 113 may be anode electrodes formed by the ITO+the protective layer. The protective layer may be made of a corrosion-resistant metal oxide. A pixel definition layer PDL and a spacer structure 20 may be arranged between any two of the first anode electrode 111, the second anode electrode 112 and the third anode electrode 113. The spacer structure 20 may be arranged on the surface of the pixel definition layer PDL. The spacer structure 20 may include a metal layer and an eave layer. The metal layer may be arranged on a surface of the pixel definition layer PDL. The eave layer may be arranged on a surface of the metal layer away from the pixel definition layer PDL. The area of the eave layer in a direction perpendicular to a stacking direction may be greater than that of the metal layer, so as to form the spacer structure 20. In some other embodiments, the spacer structure 20 may also be other structures, such as inverted trapezoidal structures or the like, which are not limited herein.

The operation at block S13: fabricating a first OLED layer on the surface of the first anode electrode, the surface of the second anode electrode, and the surface of the third anode electrode.

The operation at block S13 may specifically include: evaporating the first OLED layer on an entire surface of the substrate. The first OLED layer may include a first organic light-emitting layer and a cathode layer. The first organic light-emitting layer may be one of the blue organic light-emitting layer, the green organic light-emitting layer, or the red organic light-emitting layer.

The above-mentioned operation may specifically include: evaporating the first organic light-emitting layer and the first cathode layer successively on the entire surface of the substrate, so as to form the first OLED layer on the surface of the first anode electrode, the surface of the second anode electrode, and the surface of the third anode electrode. The first anode electrode and the first OLED layer may form the first sub-pixel.

The above-mentioned operation may further include: fabricating an encapsulating layer on the surface of the first OLED layer on the surface of the first anode electrode, thereby protecting the first OLED layer from being etched during the operation at block S14.

Specifically, as illustrated in FIG. 3, FIG. 3 is a schematic structural diagram of a specific embodiment matching with the operation at block S13 of FIG. 1. As illustrated in FIG. 3, the first OLED layer 121 may be arranged on any of the surface of the first anode electrode 111, the surface of the second anode electrode 112, and the surface of the third anode electrode 113.

The operation at block S14: etching away the first OLED layer on the surface of the second anode electrode and on the surface of the third anode electrode, so as to form the first sub-pixel.

In the present operation at block S14, removing the first OLED layer covering the surface of the second anode electrode and covering the surface of the third anode electrode through an etching process using an etching solution. The etching solution may include an acidic solution or an alkaline solution, which is not limited herein. In the present embodiment, since the second anode electrode and the third anode electrode include the corrosion-resistant protective layer, the corrosion resistance of the second anode electrode and the third anode electrode may be increased, and the second anode electrode and the third anode electrode may be prevented from being etched away.

The operation may further include: removing the first OLED layer on the surface of a part of the overhanging structures. In this way, excessive accumulation of the OLED layer on the surfaces of the overhanging structures may be avoided. The excessive accumulation may cause adverse effects. Specifically, removing the first OLED layer on the surface of the overhanging structure close to the second anode electrode and to the third anode electrode.

Further, prior to the operation at block S14, the method may further include: applying anti-etching protection of the first OLED layer on the surface of the first anode electrode, and subsequently etching the first OLED layer on the surface of the second anode electrode and on the surface of the third anode electrode. During the operation, fabricating an encapsulating layer on the surface of the first OLED layer, to protect the cathode on the surface of the first OLED layer from being etched. The cathode may be made of the ITO material. Preferably, the encapsulating layer may be made of a packaging material. In this way, when a packaging layer is fabricated on the surface of the OLED layer or on the surface of the cathode layer later, the encapsulating layer may be integrated with the packaging layer.

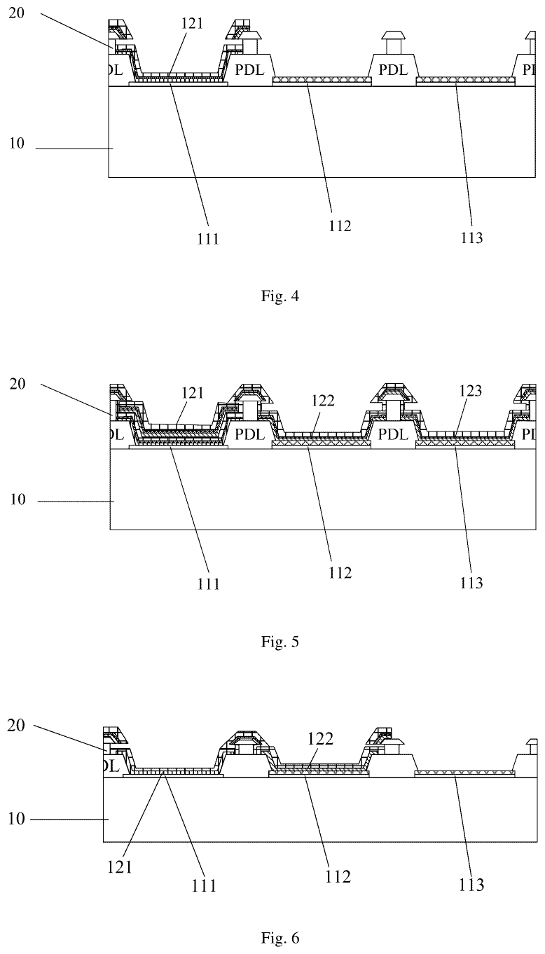

Specifically, as illustrated in FIG. 4, FIG. 4 is a schematic structural diagram of a specific embodiment matching with the operation at block S14 of FIG. 1. As illustrated in FIG. 4, etching away the first OLED layer on the surface of the second anode electrode 112 and on the surface of the third anode electrode 113, exposing the second anode electrode 112 and the third anode electrode 113. Further, removing the first OLED layer on the side of the overhanging structure 20 close to the second anode electrode 112 and the third anode electrode 113.

The operation at block S15: fabricating a second OLED layer on the surface of the first OLED layer, the surface of the second anode electrode, and the surface of the third anode electrode.

The organic light-emitting layer of the second OLED layer may be different from that of the first OLED layer, such that the second sub-pixel formed by the second anode electrode may emit light of a color different from that of the first sub-pixel. Specifically, the second OLED layer may include a second organic light-emitting layer and a cathode layer. The second organic light-emitting layer may be one of the blue organic light-emitting layer, the green organic light-emitting layer, or the red organic light-emitting layer. The second organic light-emitting layer may be not the same kind as that of the first organic light-emitting layer.

The present operation may specifically include: evaporating the second OLED layer successively on the entire surface of the substrate, enabling the second OLED layer being evaporated onto the surface of the first OLED layer, the surface of the second anode electrode and the surface of the third anode electrode.

Specifically, as illustrated in FIG. 5, FIG. 5 is a schematic structural diagram of a specific embodiment matching with the operation at block S15 of FIG. 1. As illustrated in FIG. 5, the second OLED layer 122 may cover the surface of the first OLED layer 121, the surface of the second anode electrode 112 and the surface of the third anode electrode 113.

The operation at block S16: etching away the second OLED layer on the surface of the first OLED layer and the second OLED layer on the surface of the third anode electrode, so as to form the first sub-pixel and the second sub-pixel.

The operation at block S16 may further include: fabricating an etch-resistant protective layer on the second OLED layer on the surface of the second anode electrode first, then etching the second OLED layer on the surface of the first OLED layer, and etching the second OLED layer on the surface of the third anode electrode. The protective layer on the surface of the second OLED layer may be an encapsulating layer, which is not limited herein.

The above-mentioned etching process may further include: etching the second OLED layer on the overhanging structure. Specifically, etching away the second OLED layer arranged on the side of the overhanging structure close to the first anode electrode, and etching away the second OLED layer arranged on the side of the overhanging structure close to the third anode electrode.

The etched pattern is illustrated in FIG. 6. FIG. 6 is a schematic structural diagram of a specific embodiment matching with the operation at block S16 of FIG. 1. As illustrated in FIG. 6, in the OLED display panel, the first anode electrode 111 may be provided with the first OLED layer to form the first sub-pixel; the second anode electrode 112 may be provided with the second OLED layer to form the second sub-pixel; the surface of the third anode electrode 113 may be exposed, so as to facilitate subsequent fabrication of a third OLED layer.

The operation at block S17: fabricating the third OLED layer on the surface of the first OLED layer, on the surface of the second OLED layer, and on the surface of the third anode electrode.

The operation at block S17 may specifically include: evaporating the third OLED layer on the entire surface of the substrate, so that the third OLED layer may cover the surface of the first OLED layer, the surface of the second OLED layer, and the surface of the third anode electrode.

The organic light-emitting layer of the third OLED layer may be different from any of those of the second OLED layer and the first OLED layer. Specifically, the third OLED layer may include a third organic light-emitting layer and a cathode layer. The third organic light-emitting layer may be one of the blue organic light-emitting layer, the green organic light-emitting layer, or the red organic light-emitting layer. The third organic light-emitting layer may not the same kind as the first organic light-emitting layer and the second organic light-emitting layer.

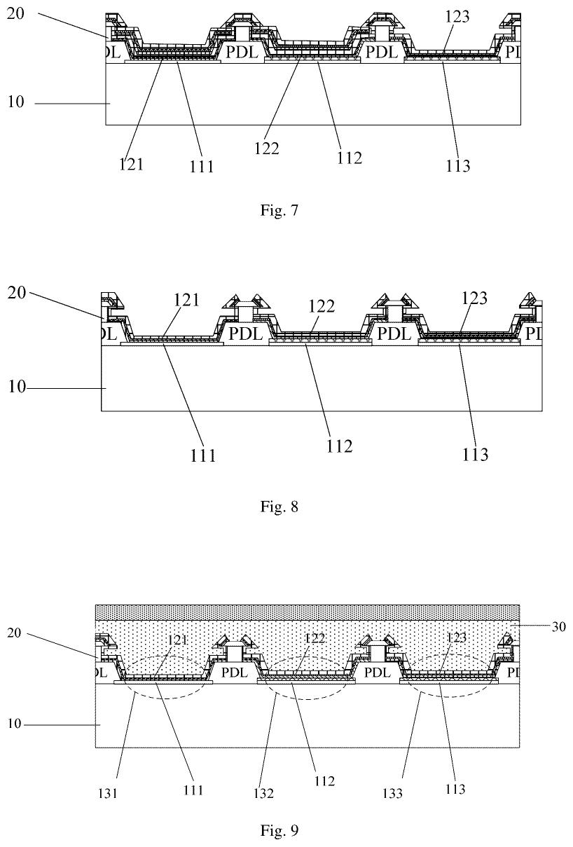

Specifically, as illustrated in FIG. 7, FIG. 7 is a schematic structural diagram of a specific embodiment matching with the operation at block S17 of FIG. 1. As illustrated in FIG. 7, the third OLED layer 123 may cover the surface of the first OLED layer 121, the surface of the second OLED layer 122, and the third anode electrode 113. The third OLED layer 123 may further cover the surface of the overhanging structure 20.

The operation at block S18: etching away the third OLED layer on the surface of the first OLED layer and on the surface of the second OLED layer to form the OLED display panel including the first sub-pixel, the second sub-pixel, and the third sub-pixel.

The operation at block S18 may specifically include: performing anti-etching protection of the third OLED layer on the surface of the third anode electrode first, etching the third OLED layer on the surface of the first OLED layer and on the surface of the second OLED layer subsequently. The present operation may specifically include: fabricating an encapsulating layer on the surface of the third OLED layer on the third anode electrode. Preferably, the encapsulating layer may be made of the packaging material. In this way, when the packaging layer is fabricated on the surface of the OLED layer or on the surface of the cathode layer later, the encapsulating layer may be integrated with the packaging layer.

Specifically, as illustrated in FIG. 8, FIG. 8 is a schematic structural diagram of a specific embodiment matching with the operation at block S18 of FIG. 1. As illustrated in FIG. 8, the OLED display panel may include the substrate 10, and the first anode electrode 111, the second anode electrode 112, and the third anode electrode 113. The first anode electrode 111, the second anode electrode 112, and the third anode electrode 113 may be arranged on the surface of the substrate 10. The surface of the first anode electrode 111 may be covered with the first OLED layer 121 to form a first sub-pixel 131. The surface of the second anode electrode 112 may be covered with the second OLED layer 122 to form a second sub-pixel 132. The surface of the third anode electrode 113 may be covered with the third OLED layer 123 to form a third sub-pixel 133.

The colors of the first sub-pixel 131, the second sub-pixel 132, and the third sub-pixel 133 may be different from each other.

In some embodiments, according to influences of manufacturing procedure fluctuations on the R/G/B microcavities (color points), the first sub-pixel 131 and/or the second sub-pixel 132 may be the green sub-pixel G or the blue sub-pixels B, and the third sub-pixel 133 may be the red sub-pixel R.

Considering that in the second anode electrode 112 and the third anode electrode 113, the protective layers are fabricated on the ITO layer surfaces, the thickness of the second anode electrode 112 and the third anode electrode 113 may be increased. The thickness of the second anode electrode 112 may be greater than that of the first anode electrode 111. The thickness of the third anode electrode 113 may be greater than that of the first anode electrode 111. Further, the thickness of the organic light-emitting layer of the first OLED layer may be greater than that of the organic light-emitting layers of the second OLED layer and the third OLED layer, so that the cathode layers of the various sub-pixels may be located on a same horizontal plane. In some embodiments, the first sub-pixel 131 may be a blue sub-pixel, the second sub-pixel 132 may be a green sub-pixel, and the third sub-pixel 133 may be a red sub-pixel. This is because a luminous efficiency of the blue sub-pixel is relatively low, and thickening the organic light-emitting layer of the blue sub-pixel may increase the luminous efficiency.

Further, considering that the thickness of the second anode electrode 112 may be greater than that of the first anode electrode 111, and the thickness of the third anode electrode 113 may be greater than that of the first anode electrode 111, in a further embodiment, grooves may be defined on the surface locations of the planarization layer of the substrate matching with the second anode electrode 112 and the third anode electrode 113, so that the surfaces of the second anode electrode 112 and the third anode electrode 113 are on the same horizontal plane as the surface of the first anode electrode 111, thereby eliminating a height difference between the second anode electrode 112 and the first anode electrode 111, and eliminating a height difference between the third anode electrode 113 and the first anode electrode 111. The depth of the grooves may be set according to the thickness difference between the second anode electrode 112 and the first anode electrode 111 and according to the thickness difference between the third anode electrode 113 and the first anode electrode 111. Specifically, the depth of the groove for the second anode electrode 112 may further be different from that of the groove for the third anode electrode 113. The depth of the groove for the second anode electrode 112 may be specifically designed according to the thickness of the protective layer on the surface of the second anode electrode 112, the depth of the groove for the third anode electrode 113 may be specifically designed according to the thickness of the protective layer on the surface of the third anode electrode 113, which are not limited herein.

After the operation at block S18, the method may further include: fabricating the packaging layer on the surface of the substrate, so as to form an OLED panel. The packaging layer may cover the surface of the first OLED layer, the surface of the second OLED layer, and the surface of the third OLED layer, and may cover the surface of a spacer layer. The packaging layer may include a first encapsulating layer, an organic packaging layer, a second encapsulating layer, or the like, which is not limited herein.

The present disclosure may further provide an OLED display panel. The OLED display panel may be fabricated by adopting the manufacturing method of the OLED display panel described in the above-mentioned method embodiments. Specifically, as illustrated in FIG. 9, FIG. 9 is a schematic structural diagram of a specific embodiment of the OLED display panel according to the present disclosure. As illustrated in FIG. 9, the OLED display panel may include the substrate 10.

The first anode electrode 111, the second anode electrode 112, and the third anode electrode 113 may be arranged on the surface of the substrate 10. The pixel definition layer PDL and the spacer structure 20 may be arranged between every two of the first anode electrode 111, the second anode electrode 112, and the third anode electrode 113. The spacer structure 20 may be arranged on the pixel definition layer PDL.

The first OLED layer 121 may be arranged on the surface of the first anode electrode 111, and form the first sub-pixel 131. The second OLED layer 122 may be arranged on the second anode electrode 112, and form the second sub-pixel 132. The third OLED layer 123 may be arranged on the third anode electrode 113, and form the third sub-pixel 133.

A packaging layer 30 may further be arranged on the surface of the first sub-pixel 131, the surface of the second sub-pixel 132, the surface of the third sub-pixel 133, and the surface of the spacer structure 20. The packaging layer 30 may include a plurality of layers, which is not limited herein.

The advantages of the present embodiment are that: by differentially fabricating the anodes of the three sub-pixels in each pixel unit, so as to enable the anodes of two of the sub-pixels to be corrosion-resistant, optical performances of each sub-pixel may be guaranteed, and the stability of the performances of the OLED device may further be guaranteed.

The above are only implementations of the present disclosure, and do not limit the patent scope of the present disclosure. Any equivalent changes to the structure or processes made by the description and drawings of the present disclosure or directly or indirectly used in other related technical field are included in the protection scope of the present disclosure.

1. A manufacturing method of an organic light emitting diode (OLED) display panel, comprising:
providing a substrate;
fabricating a first anode electrode, a second anode electrode, and a third anode electrode on the substrate; wherein a corrosion resistance of the second anode electrode is better than that of the first anode electrode, and a corrosion resistance of the third anode electrode is better than that of the first anode electrode;
fabricating a first OLED layer on a surface of the first anode electrode, a surface of the second anode electrode, and a surface of the third anode electrode;
etching away the first OLED layer on the surface of the second anode electrode and the first OLED layer on the surface of the third anode electrode to form a first sub-pixel;
fabricating a second OLED layer on a surface of the first OLED layer, the surface of the second anode electrode, and the surface of the third anode electrode;
etching away the second OLED layer on the surface of the first OLED layer and the second OLED layer on the surface of the third anode electrode, to form the first sub-pixel and a second sub-pixel;
fabricating a third OLED layer on the surface of the first OLED layer, a surface of the second OLED, and the surface of the third anode electrode;
etching away the third OLED layer on the surface of the first OLED layer and the third OLED layer on the surface of the second OLED layer, to form the OLED display panel comprising the first sub-pixel, the second sub-pixel, and a third sub-pixel.

2. The manufacturing method of the OLED display panel as claimed in claim 1, wherein
the first anode electrode comprises indium tin oxide (ITO) material, the second anode electrode and the third anode electrode comprise corrosion-resistant material; wherein the corrosion-resistant material comprises a metal oxide.

3. The manufacturing method of the OLED display panel as claimed in claim 2, wherein
each of the second anode electrode and the third anode electrode comprises a multilayer structure, each of the second anode electrode and the third anode electrode comprises the ITO material and a protective layer, the protective layer is arranged on a surface of the ITO material, the protective layer comprises molybdenum oxide or tungsten oxide.

4. The manufacturing method of the OLED display panel as claimed in claim 2, wherein
the second anode electrode comprises the molybdenum oxide or the tungsten oxide, the third anode electrode comprises molybdenum oxide or tungsten oxide.

5. The manufacturing method of the OLED display panel as claimed in claim 1, wherein
the fabricating the first anode electrode, the second anode electrode, and the third anode electrode on the substrate comprises:
fabricating a plurality of ITO layers on a surface of the substrate, to obtain the first anode electrodes;
fabricating a protective layer on surfaces of two of the first anode electrodes in each pixel unit, so as to obtain the second anode electrode and the third anode electrode; wherein the protective layer comprises molybdenum oxide or tungsten oxide.

6. The manufacturing method of the OLED display panel as claimed in claim 5, wherein
a thickness of the protective layer ranges from 10 angstrom to 200 angstrom.

7. The manufacturing method of the OLED display panel as claimed in claim 5, wherein
a thickness of the protective layer of the third anode electrode is greater than that of the protective layer of the second anode electrode.

8. The manufacturing method of the OLED display panel as claimed in claim 1, wherein
after the operation of fabricating the first anode electrode, the second anode electrode, and the third anode electrode on the substrate, the method further comprises:
fabricating a pixel definition layer on a surface of the substrate, and exposing the surface of the first anode electrode, the surface of the second anode electrode, and the surface of the third anode electrode;
fabricating an overhanging structure on a surface of the pixel definition layer, to facilitate evaporation of an OLED layer; the overhanging structure comprises a metal layer and an eave layer, the metal layer is arranged on the surface of the pixel definition layer, the eave layer is arranged on a surface of the metal layer away from the pixel definition layer, an area of the eave layer in a direction perpendicular to a stacking direction is greater than that of the metal layer.

9. The manufacturing method of the OLED display panel as claimed in claim 1, wherein
the first sub-pixel is a green sub-pixel or a blue sub-pixel, the third sub-pixel is a red sub-pixel.

10. The manufacturing method of the OLED display panel as claimed in claim 7, wherein
the first sub-pixel is a blue sub-pixel, the second sub-pixel is a green sub-pixel, and the third sub-pixel is a red sub-pixel.

11. The manufacturing method of the OLED display panel as claimed in claim 1, wherein
the substrate comprises a planarization layer;
the providing the substrate comprises:
defining grooves on surface locations of the planarization layer of the substrate matching with the second anode electrode and the third anode electrode, allowing surfaces of the second anode electrode and the third anode electrode to be on a same horizontal plane as the surface of the first anode electrode.

12. An OLED display panel, comprising:
a substrate;
a first anode electrode, a second anode electrode and a third anode electrode spaced apart from each other and arranged on a surface of the substrate; wherein a corrosion resistance of the second anode electrode is better than that of the first anode electrode, and a corrosion resistance of the third anode electrode is better than that of the first anode electrode;
a pixel definition layer, arranged at interval positions among the first anode electrode, the second anode electrode, and the third anode electrode, and partially extending to a surface of the first anode electrode, a surface of the second anode electrode, and a surface of the third anode electrode;
a first OLED layer, a second OLED layer and a third OLED layer, wherein the first OLED layer is arranged on the surface of the first anode electrode, the second OLED layer is arranged on the surface of the second anode electrode, and the third OLED layer is arranged on the surface of the third anode electrode.

13. The OLED display panel as claimed in claim 12, wherein
the first anode electrode comprises ITO material, the second anode electrode and the third anode electrode comprise corrosion-resistant material; wherein the corrosion-resistant material comprises a metal oxide.

14. The OLED display panel as claimed in claim 13, wherein
each of the second anode electrode and the third anode electrode comprises a multilayer structure, each of the second anode electrode and the third anode electrode comprises the ITO material and a protective layer, the protective layer is arranged on a surface of the ITO material, the protective layer comprises molybdenum oxide or tungsten oxide.

15. The OLED display panel as claimed in claim 13, wherein
the second anode electrode comprises the molybdenum oxide or the tungsten oxide, the third anode electrode comprises molybdenum oxide or tungsten oxide.

16. The OLED display panel as claimed in claim 14, wherein
a thickness of the protective layer ranges from 10 angstrom to 200 angstrom.

17. The OLED display panel as claimed in claim 14, wherein
a thickness of the protective layer of the third anode electrode is greater than that of the protective layer of the second anode electrode.

18. The OLED display panel as claimed in claim 14, wherein
the first anode electrode and the first OLED layer form a first sub-pixel, the second anode electrode and the second OLED layer form a second sub-pixel, and the third anode electrode and the third OLED layer form a third sub-pixel; and
the first sub-pixel is a green sub-pixel or a blue sub-pixel, the third sub-pixel is a red sub-pixel.

19. The OLED display panel as claimed in claim 17, wherein
the first anode electrode and the first OLED layer form a first sub-pixel, the second anode electrode and the second OLED layer form a second sub-pixel, and the third anode electrode and the third OLED layer form a third sub-pixel; and
the first sub-pixel is a blue sub-pixel, the second sub-pixel is a green sub-pixel, and the third sub-pixel is a red sub-pixel.

20. The OLED display panel as claimed in claim 12, wherein
the substrate comprises a planarization layer; and
the substrate defines grooves on surface locations of the planarization layer matching with the second anode electrode and the third anode electrode, and surfaces of the second anode electrode and the third anode electrode are on a same horizontal plane as the surface of the first anode electrode.
